(19) United States
(12) Patent Application Publication
(10) Pub. No.: US 2003/0201802 A1
(43) Pub. Date: Oct. 30, 2003

(54) Driver and amplifier circuitry

(76) Inventor: Brian D. Young, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/133,040

(22) Filed: Apr. 26, 2002

(51) Int. Cl. H03B 1/00

(52) U.S. Cl. 327/108

(57) ABSTRACT

A transmission circuit (150) provides two outputs. The two outputs carry both signal information as a differential voltage and carry a signal as a common mode voltage. The differential voltage is sensed by a comparator. The common mode voltage is sensed by a single-ended amplifier. This transmission circuit is combined with another one so that the signal, which is carried as the common mode signal, is carried on the first pair of differential signals as well as a second pair of differential signals. Thus, one signal is carried as a differential signal on two lines, a third signal is carried as a differential signal on two additional lines, and the common mode signal is carried on all four lines. The first two lines provide the differential signal which is sensed by a comparator. The second pair of lines carries a differential signal which is sensed by another comparator. The first pair of lines is combined to provide a common mode signal. The second pair of lines is combined to provide a complementary common mode signal. The true and the complementary common mode signals are sensed by a comparator. Thus, four lines carry 3 differential signals which are all capable of high speed and may be synchronous or asynchronous.

### FIELD OF THE INVENTION

The invention relates to driver and amplifier circuitry, and more particularly to driver and amplifier circuitry which has at least one use in multi-channel signaling that includes differential signaling.

### BACKGROUND OF THE INVENTION

Transmission of data has been achieved in several ways. Typically the most efficient way, from a number of transmission lines involved or outputs involved, is to use a single line for each data signal. This style of signaling is commonly called single-ended signaling. Another technique, which is much faster, is to use two lines per signal and for them to be differential, i.e., using differential signals. Another technique is to use a high-speed carrier and have data, in one form or another, modulating that carrier. The technique using modulation is generally a wireless technique and has, of course, the advantage of not requiring wires. A disadvantage of it, though, is that is does require special electronics to assemble all that information and get it transmitted properly, and also on the receiving end there may be not just electronics but antennas and other space-requiring hardware involved. This is generally not practical for information transfer within a circuit board or within a product such as a computer.

The primary reason that differential signaling is significantly faster than single-ended signaling is that the majority of noise that occurs will occur on both lines and has the effect of being cancelled out. This is commonly called common mode rejection. The voltage differential between the two complementary signals provides the logic state information of the data signal. Thus, at the receiving end it is the voltage differential that is detected. Noise will affect both signals equally so the differential remains the same as that transmitted.

The disadvantages of having two wires per signal, however, are significant. In the case of an integrated circuit transmitting a differential signal, that means the integrated circuit itself has two output pins for each signal, and the pin count significantly impacts cost and reliability as well as size of the integrated circuit itself. The number of pins affects the cost of making the semiconductor wafers that have the integrated circuit die as well as the package which houses or carries the integrated circuit when shipped to the end user. The size aspect impacts the end user because the integrated circuit is generally located on a product. The available space on a printed circuit board that contains the integrated circuit in the product is typically desired to be as small as possible. It is advantageous if there is less space taken up by the integrated circuit.

By way of example, a channel of data may be 72 pins. The 72 pins represent both the true and complements of the information. If single-ended signaling were utilized instead, only 36 pins would be required. On the other hand if differential signaling is utilized, for each additional channel, seventy-two more pins are required instead of thirty-six for single-ended. Thus there is a significant disadvantage in adding an additional channel. Accordingly, there is a need for high-speed data transmission without having to add additional pins.

### BRIEF DESCRIPTION OF THE DRAWINGS

FIG. 1 is a circuit diagram of a prior art circuit.

FIG. 2 is a timing diagram relevant to the circuit of FIG. 1.

FIG. 3 is a circuit diagram of a prior art circuit.

FIG. 4 is a timing diagram relevant to the circuit of FIG. 3.

FIG. 5 is a circuit diagram of a circuit according to one embodiment of the present invention.

FIG. 6 is a circuit diagram of a transmission circuit of FIG. 5 according to one embodiment of the present invention.

FIG. 7 is a circuit diagram of a receiving circuit of FIG. 5 according to one embodiment of the present invention.

FIG. 8 is a circuit diagram representation of a transmission circuit and a portion of a receiving circuit according to one embodiment of the present invention.

### DETAILED DESCRIPTION

Multi-channel differential signaling operates by exploiting the common-mode signal on a differential pair. Normally the common-mode is avoided because it is noisy, and in differential signaling, the differential receiver rejects the common-mode signal. In multi-channel differential signaling, the common-mode signals on two differential pairs are driven in complementary fashion so that a third differential signal is created from the two common-mode signals. Again a differential receiver is used to detect the differential signal while rejecting common-mode noise.

Multi-channel differential signaling provides three differential signals using just four wires. There are two pairs of standard differential signals plus one additional differential signal encoded on the common-modes of the two standard differential pairs. The benefit of multi-channel differential signaling is either a 50% increase in bandwidth for a given number of wires, or a 33% reduction in wires for a given bandwidth.

To implement multi-channel differential signaling in a technically strong way, a fully current steering driver is needed that drives three differential channels on four wires while drawing substantially constant current from the power supply. In addition, it is desirable for the driver circuit to be low-power, process insensitive, and low noise. The present invention meets these requirements.

First, the prior art will be discussed.

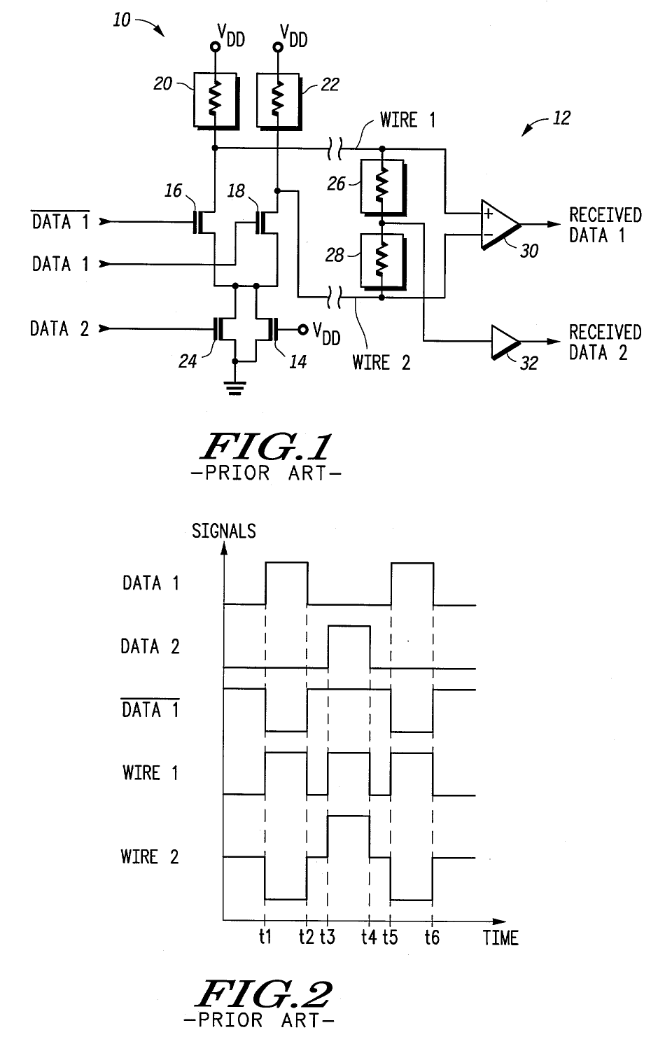

Shown in prior art FIG. 1 is a transmission circuit 10 and a receive circuit 12. Transmission circuit 10 comprises an N channel transistor 14, an N-channel transistor 16, an N-channel transistor 18, a resistive element 20, a resistive element 22, and an N-channel transistor 24. Receive circuit 12 comprises a resistive element 26, a resistive element 28, a comparator 30, and a single-ended amplifier 32. Transmission circuit 10 utilizes DATA 1, and DATA 2 to generate a pair of signals on WIRE 1 and WIRE 2 which contain both a differential signal and a common mode signal. The common mode signal represents DATA 2. The differential signal is DATA 1 and \overline{DATA1}. \overline{DATA1}and \overline{DATA1}are maintained within a voltage range which ensures that transistors 16 and 18 do not become non-conductive. Transistor 24 is switched between a conductive and a less conductive or nonconductive state. Transistor 14 ensures that there is some current flowing through transistors 16 and 18. Transistors 16, 18, 24, 14, and resistive elements 20 and 22 comprise a differential amplifier that is modulated by DATA 2.

Resistive element 20 has a first terminal connected to a power supply terminal VDD and a second terminal shown as being connected to WIRE 1. Resistive element 22 has a first terminal connected to VDD and a second terminal connected to WIRE 2. Transistor 16 has a drain connected to the second terminal of resistor 20, a gate for receiving \overline{DATA1}and a source. Transistor 24 has a drain connected to the source of transistor 16, a gate for receiving DATA 2 and a source connected to a negative supply terminal shown as ground. Transistor 14 has a drain connected to the source of transistor 16, a gate connected to a positive power supply terminal, shown as VDD, and a source connected to negative power supply terminal, shown as ground. Transistor 18 has a drain connected to the second terminal of resistive element 22, a gate for receiving DATA 1, and a source connected to the drain of transistor 14.

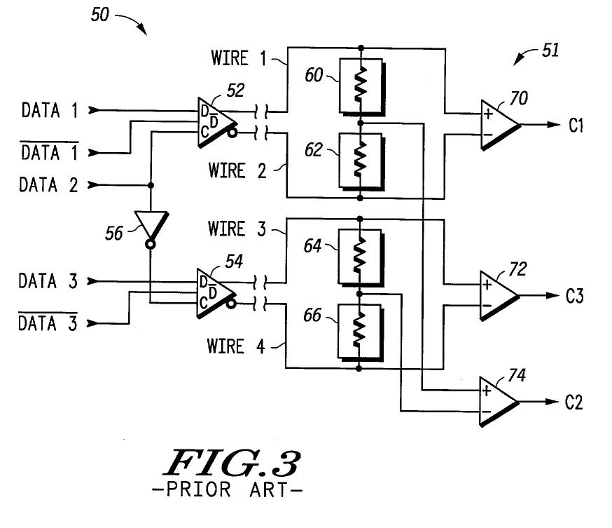

As shown in prior art FIG. 2, DATA 1 begins as a logic low so that \overline{DATA1}begins as a logic high. DATA 2 begins as a logic low. At time t1 there is a transition of the DATA 1 signal from a logic low to a logic high. Similarly, \overline{DATA1} switches from a logic high to a logic low. WIRE 1 switches from a lower voltage to a higher voltage in response to this. Similarly, WIRE 2 switches from a higher voltage to a lower voltage. The voltages on WIRE 1 and WIRE 2 reflect these different logic states with a voltage differential of about 600 millivolts (mvolts). At time t2 DATA 1 switches from a logic high to a logic low and has the effect of switching WIRE 1 from a higher voltage back to lower voltage and WIRE 2 from a lower voltage to a higher voltage. At time t3 when DATA 1 is a logic low, DATA 2 switches to a logic high. This is reflected in WIRE 1 and WIRE 2 both switching to a higher voltage. However, the difference between WIRE 1 and WIRE 2 does not change. This is a change in the common mode signal or common mode level between WIRE 1 and WIRE 2.

At time t4 DATA 2 switches back to a logic low and this is again reflected in WIRE 1 and WIRE 2 switching back to the lower voltage state. The amount of reduction voltage corresponds to that of DATA 2. Again, the time t5 shows DATA 1 switching to the logic high which results in WIRE 1 and WIRE 2 switching logic states, WIRE 1 switching to a relatively higher voltage, WIRE 2 switching to a relatively lower voltage.

Resistors 20, 22, 26 and 28 are conveniently chosen to each be 50 ohms. This is to provide impedance matching at 50 ohms which is the typical industry standard. In a differential amplifier a termination of 50 ohms is typically achieved with a 100-ohm resistor connected between the differential pair. In this case the 100 ohms is achieved by two 50-ohm transistors. Resistors 26 and 28 provide the 100 ohms and the node between these two resistors provides the common mode signal which is utilized as a data signal. The resistive elements 20 and 22 are selected at 50 ohms similarly to match the impedance to avoid reflections. Since the common mode signal is being utilized as a data signal, it is more important to provide for impedance matching which minimizes the reflections. Resistors 20, 22, 26 and 28 may be typical linear resistors but these resistive elements may also be replaced by transistors which achieve similar type of impedance at the voltages that are utilized. In current integrated circuits a typical VDD would be 1.8 to 2.5 volts. It is clear the industry is moving to lower and lower voltages so VDD may be a lower voltage. This could also result in the voltage differential between WIRE 1 and WIRE 2 being less than 600 mvolts. That would not present a problem or a different approach in concept to that shown in FIG. 1.

WIRE 1 and WIRE 2 are representative of what may be a fairly lengthy wire. It could either be just a wire on a printed circuit board, or it could be a cable connection between two computers. The connection of resistor 20 to WIRE 1 is simply a connection to an output terminal of an integrated circuit which in turn is connected to WIRE 1. Similarly, the drain of transistor 18, as shown, is connected to WIRE 2. This is representative of an output of an integrated circuit being connected to WIRE 2. The extension of WIRE 1 and WIRE 2 are connections between an integrated circuit which includes transmission circuit 10 to a receiving circuit 12. Receiving circuit 12 could be resident on an integrated circuit either on a similar printed circuit board, a different printed circuit board, or some other product different from the product that contains circuit 10.

Comparator 30 of receive circuit 12 has a plus input connected to WIRE 1 and a minus input connected to WIRE 2 and provides an output representative of DATA 1. Resistive element 26 has a first terminal connected to WIRE 1, and a second terminal. Resistive element 28 has a first terminal connected to WIRE 2 and a second terminal connected to the second terminal of resistive element 26. The connection of the second terminals of resistive elements 26 and 28 provide the common mode voltage between the signals present on WIRE 1 and WIRE 2. Single-ended amplifier 32 has an input connected to the second terminals of resistive elements 26 and 28 and has an output representative of DATA 2 and is shown in FIG. 1 as received DATA 2.

The common mode voltage on the input of single-ended amplifier 32 is representative of the DATA 2 signal which is input into transistor 24. The common mode voltage is the voltage which is half way between the differential voltages. In addition to the signal DATA 2 there is noise on the common mode voltage. This noise is expected and anticipated in a differential amplifying system. The presence of noise in the common mode signal, however, does means that difficulty of reliably detecting the common mode signal will be greater than for detecting the differential signal present on WIRE 1 and WIRE 2. This is the typical distinction between single-ended and differential sensing. That there is a differential signal present on WIRE 1 and WIRE 2 allows for high speed of detection of the logic state. The noise that is accumulated in the common mode signal is, in effect, rejected because amplifier 30 is looking at a difference only and not at the absolute values of the signals whereas the common mode signal is detected at only a single input which is available to provide the information. Accordingly, the rate that the logic state can be detected is significantly slower, typically by an order of magnitude. Thus, the transmission and receive circuits shown in FIG. 1 provide both a high speed differential signal and a common mode signal which is utilized as a single-ended input for single-ended amplifier 32, which is substantially slower than the differential amplifier for reliable detection.

A significant advantage is that a standard high-speed differential signal is received on two lines and, in addition, a data signal is received as the common mode signal and detected as a data signal. Accordingly, there is a benefit of having an additional signal in addition to the high-speed signal. Although it is slower in speed, it may be useful for a number of things. One example would be handshaking control, flow control, status and other functions which may not need the high-speed data rate of the differential signal. These signals are shown in FIG. 2.

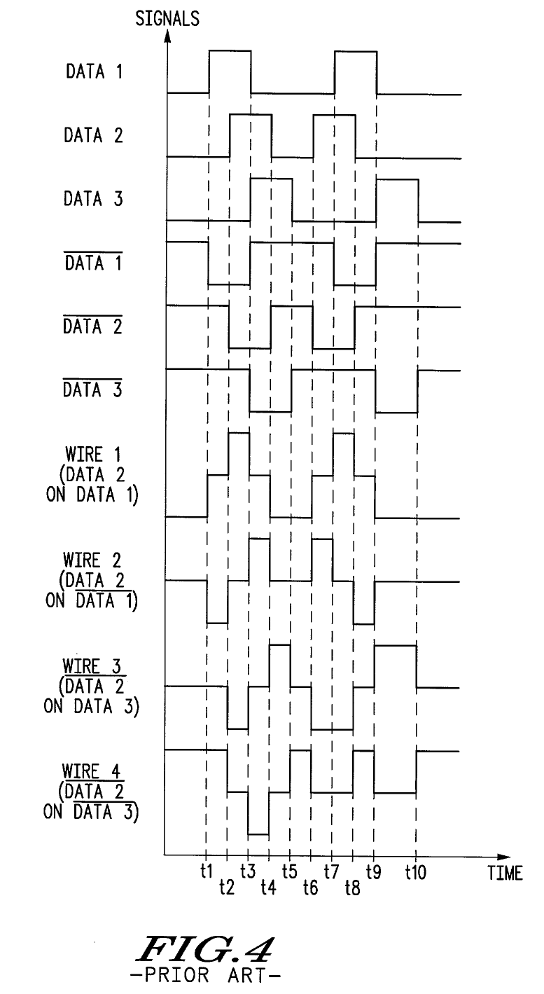

Shown in prior art FIG. 3 is a transmission circuit 50 and a receiving circuit 51. Transmission circuit 50 comprises a transmit circuit 52 and a transmit circuit 54 which are constructed in the same manner as transmitting circuit 10 in FIG. 1. Circuit 50 further comprises an inverter 56. Transmit circuits 52 and 54 have two complementary data inputs and having a common mode input. Transmit circuit 52 has a true and a complementary data inputs receiving DATA 1 and \overline{DATA1} as in similar fashion in FIG. 1. A common mode input similarly receives DATA 2. Transmitting circuit 54 has a pair of data inputs for receiving a DATA 3 and a \overline{DATA3} and a common mode input coupled to an output of inverter 56. The input of inverter 56 receives DATA 2. Circuit 50 would be resident on a single integrated circuit. Transmitting circuit 52 would have a true output and a complementary output coupled to WIRE 1 and WIRE 2, respectively. Similarly, transmitting circuit 54 has a true and complementary output coupled to WIRE 3 and WIRE 4, respectively.

Receiving circuit 51 comprises a pair of resistors 60 and 62, and a pair of resistors 64 and 66. Resistors 60 and 62, as a pair, terminate WIREs 1 and 2 in similar fashion to resistors 26 and 28 terminating WIRE 1 and WIRE 2 of FIG. 1. Resistive elements 64 and 66 terminate WIRE 3 and WIRE 4. Receiving circuit 51 further comprises comparators 70, 72 and 74. Comparator 70 has a plus input coupled to WIRE 1 and a minus input coupled to WIRE 2. This is in conventional differential amplifier fashion having a comparator coupled to a differential input. Comparator 70 provides an output C1 which is representative of DATA 1. Similarly, comparator 72 has a plus input coupled to WIRE 3 and a minus input coupled to WIRE 4 in conventional differential signal amplification techniques. Comparator 72 thus detects the difference between WIRE 3 and WIRE 4 and provides an output representative of data channel 3 and shown as signal C3 in FIG. 3. Comparator 74 also detects a differential signal. In this case, however, comparator 74 detects a difference in common mode voltage in two separate common mode signals.

Comparator 74 has a plus input coupled to the connection between resistors 60 and 62. Comparator 74 has a minus input coupled to the connection between resister 64 and 66. Resistor 60 has a first terminal connected to WIRE 1 and a second terminal connected to the plus input of comparator 74. Resistor 62 has a first terminal connected to WIRE 2 and a second terminal connected to the plus input of comparator 74. Resister 64 has a first terminal connected to WIRE 3 and a second terminal connected to the minus input of comparator 74. Resistor 66 has a first terminal connected to WIRE 4 and a second terminal to the minus input of comparator 74. The result of this configuration is that four differential wires are utilized to produce not just two differential signals but three. As differential signals they are thus potentially high-speed. Thus, there is an increase in differential signals of one for every two that are generated using two lines per differential signal. Thus, for a given number of pins you get a 50 percent increase in the number of differential signals that are available. The differential signals are ones that can be operated at high speed. Further, these three data signals, DATA 1, DATA 2 and DATA 3 do not have to be synchronized with each other for this operation.

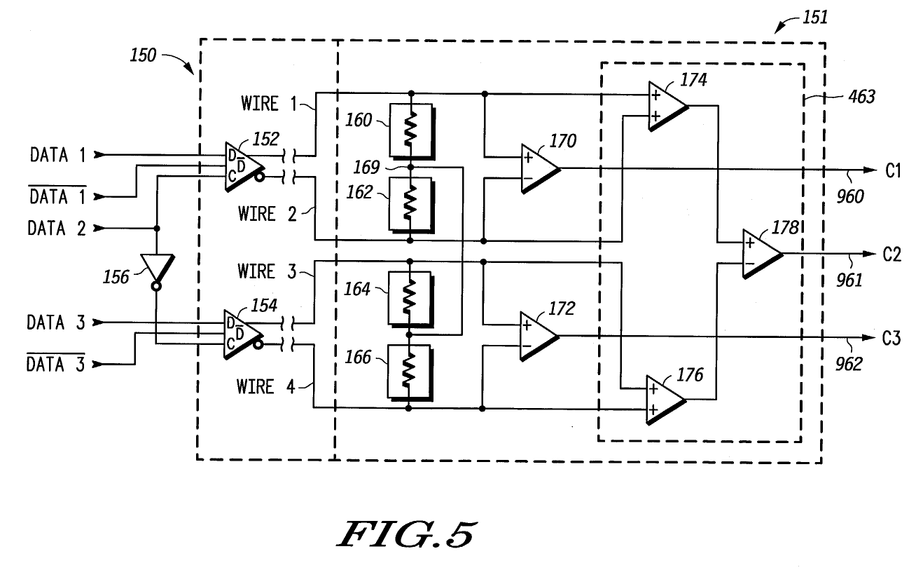

Shown in prior art FIG. 4 is a timing diagram of a possible combination of data signals, DATA 1, 2 and 3. This shows DATA 1 switching beginning at a voltage representative of a logic 0 and switching to a voltage representative of a logic 1. This occurs at time t1. At time t2 data signal 2 switches from a logic low to a logic high and then some time later at time t3 DATA 1 switches to a logic low, DATA 3 switches to a logic high and DATA 2 remains at a logic high. At a time t4 DATA 2 switches to a logic low and at a time t5 DATA 3 switches to a logic low. Complementary signals \overline{DATA}1, 2 and 3 switch in the reverse states to those of the true states which they complement. WIRE 1 shows that DATA 2 and DATA 1 are combined. Thus at time t1 DATA 1 is a logic high so that WIRE 1 switches to a voltage that is higher than the logic low condition. At time t2 while DATA 1 is high, DATA 2 switches to a logic high so that WIRE 1 increases in voltage and response. WIRE 2, which carries DATA 2 combined with \overline{DATA1,}shows that at time t1 WIRE 2 switches to a lower voltage in response to \overline{DATA1} switching low. At time t2 WIRE 2 switches to a higher voltage in response to DATA 2 switching to a logic high. Thus, you can see at time t2 both the voltages on WIRE 1 and WIRE 2 increased so that the differential between the two did not change but both WIRE 1 and WIRE 2 did increase in voltage. Thus, this is indicative of an increase in the common mode voltage at this time. This increase in common mode voltage is representative of the logic high of DATA 2. A similar situation occurs beginning at time t6 in which DATA 2 switches from a logic low to a logic high which causes an increase in voltage in WIRE 1 and WIRE 2 at time t6. At time t7 when DATA 1 switches to a logic high and \overline{DATA1} thus switches to a logic low, there is an increase in the voltage on WIRE 1 and a decrease in the voltage on WIRE 2. This does cause a change in the difference between WIRE 1 and WIRE 2. This difference in voltage between WIRE 1 and WIRE 2 is representative of the logic state change which occurs on DATA 1. In this case there is no change in the common mode voltage, that is to say the average voltage of the two remains the same thus indicating that there is no change in the logic state of the signal carried in the common mode signal.

A similar situation is achieved with WIREs 3 and 4. At time t2 DATA 2, the signal carried in the common mode voltage, causes both WIRE 3 and WIRE 4 to reduce in voltage. At time t3 DATA 3 switches from a logic low to a logic high and \overline{DATA3} switches from a logic high to a logic low which results in WIRE 3 increasing in voltage and WIRE 4 decreasing in voltage. The increase in voltage on WIRE 3 is shown to be substantially the same as the decrease in voltage on WIRE 4. Thus, there is no change in the common mode voltage which is the desired result. This indicates that there is no change in the signal carried in the common mode which is accurate because DATA 2 does not change logic state at time t3.

At time t4 DATA 2 does change logic state, as does \overline{DATA2}. \overline{DATA2} increases from a logic low to a logic high, which causes an increase in voltage in both WIRE 3 and WIRE 4. In this case, only DATA 2 is changing and not DATA 3. Thus, the desired result is that the common mode voltage changes but the differential does not change. This is shown in WIRE 3 and WIRE 4 as being the case. At time t5 DATA 3 and \overline{DATA3} switch logic states while DATA 2 and \overline{DATA2,}which is output by inverter 56, do not. Thus, WIRE 3 and WIRE 4 should change voltage in the opposite direction which is shown in FIG. 4 as WIRE 3 reduces in voltage at time T5 while WIRE 4 increases in voltage at time T5. The effect then is to have a voltage differential on WIRE 1 and WIRE 2 representative of DATA 1 which is conventional for differential amplifying in the high speed that is available with such technique. Similarly, WIRE 3 and WIRE 4 have a voltage differential which is input into comparator 72, as is desired for differential amplifying operation. Thus, an additional differential signal is available through common mode signals present between resistors 60, 62 and between resisters 64 and 66.

The common mode signal, which is the true representation of DATA 1, is provided between resistors 60 and 62. The complementary common mode representation of DATA 2 is between resistors 64 and 66. Thus, there is a differential signal and therefore a high-speed signal established for DATA 2. WIREs 1, 2, 3 and 4 would be run close together so that any noise generated on one would occur on the other so that the noise would be able to be rejected based on the fact of differential sensing. This differential sensing would be equally true for DATA 2 as it is for DATA 1 and DATA 3. The circuit of FIG. 1 which is replicated by virtue of transmission circuits 52 and 54 in FIG. 3 are shown as being made using N-channel transistors. P-channel transistors could also be utilized by reversing the polarity of the power supplies and rearranging the resistors and the current source and altering the power supply connections accordingly. Another alternative is to ensure that the DATA 2 signal does not make transistor 24 non-conductive, in which case it may not be necessary to utilize a transistor such as transistor 14.

The present invention will now be described.

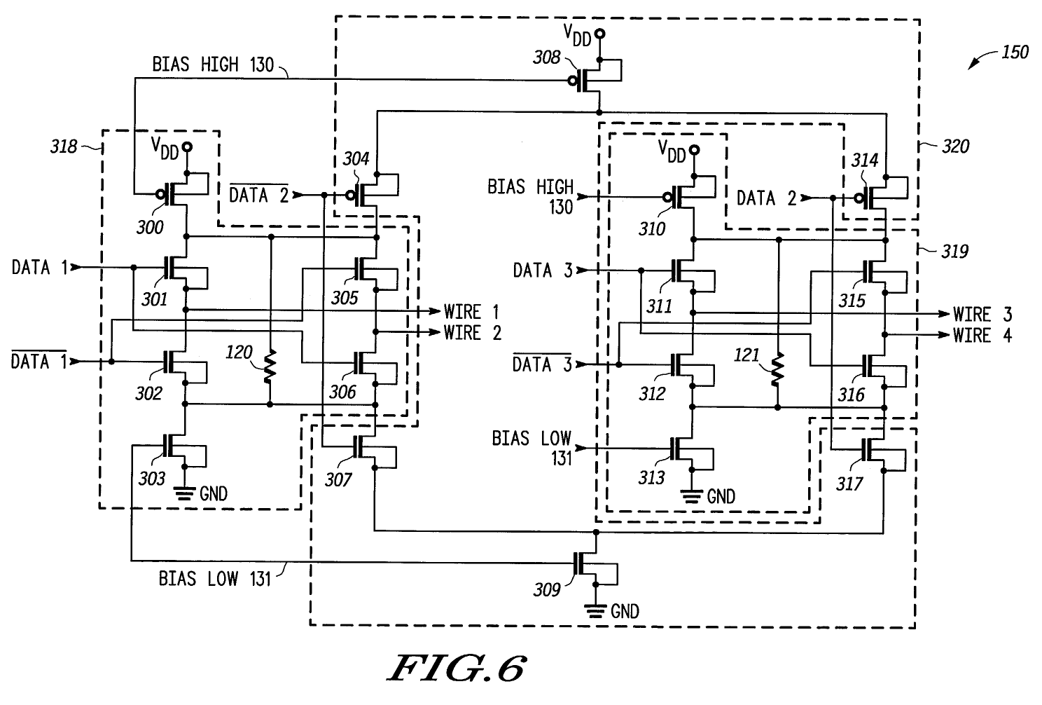

Illustrated in FIG. 5 is a transmission circuit 150, a receiving circuit 151, and an inverter 156 in accordance with one embodiment of the present invention. Transmission circuit 150 comprises a transmit circuit 152 and a transmit circuit 154 which receive complementary signals DATA 2 and \overline{DATA2}from the input and output of inverter 156, respectively. Transmit circuits 152 and 154 have two complementary data inputs and have a common mode input. Transmit circuit 152 has a true data input and a complementary data input receiving DATA 1 and \overline{DATA1,}respectively. A common mode input similarly receives DATA 2. Transmitting circuit 154 has a pair of data inputs for receiving a DATA 3 and a \overline{DATA3}and a common mode input coupled to an output of inverter 156. The input of inverter 156 receives DATA 2. In one embodiment of the present invention, circuit 150 may be resident on a single integrated circuit. Alternate embodiments of the present invention may locate various portions of the circuitry in FIG. 5 on one or more integrated circuits. Transmitting circuit 152 would have a true output and a complementary output coupled to WIRE 1 and WIRE 2, respectively. Similarly, transmitting circuit 154 has a true and complementary output coupled to WIRE 3 and WIRE 4, respectively.

Receiving circuit 151 includes a pair of resistors 160 and 162, and a pair of resistors 164 and 166. Resistors 160 and 162, as a pair, terminate WIREs 1 and 2 in similar fashion to resistors 26 and 28 terminating WIRE 1 and WIRE 2 of FIG. 1. Resistive elements 164 and 166 terminate WIRE 3 and WIRE 4. Receiving circuit 151 further includes comparators 170 and 172. Comparator 170 has a plus input coupled to WIRE 1 and a minus input coupled to WIRE 2. This is in conventional differential amplifier fashion having a comparator coupled to a differential input. Comparator 170 provides an output C1 960 which is representative of DATA 1. Similarly, comparator 172 has a plus input coupled to WIRE 3 and a minus input coupled to WIRE 4 according to conventional differential signal amplification techniques. Comparator 172 thus detects the difference between WIRE 3 and WIRE 4 and provides an output representative of data channel 3 and shown as signal C3 962 in FIG. 5.

Receiving circuit 151 further includes summing circuits 174 and 176 and comparator 178. Summing circuit 174 has a first input coupled to WIRE 1 and a second input coupled to WIRE 2. Summing circuit 174 provides an output which is coupled to a plus input of comparator 178, wherein the output of summing circuit 174 is representative of the common mode voltage on WIRE 1 and WIRE 2. Summing circuit 176 has a first input coupled to WIRE 3 and a second input coupled to WIRE 4. Summing circuit 176 provides an output which is coupled to a minus input of comparator 178, wherein the output of summing circuit 176 is representative of the common mode voltage on WIRE 3 and WIRE 4. Comparator 178 provides an output C2 961 which is representative of DATA 2. Comparator 178 also detects a differential signal. In this case, however, comparator 178 detects a difference in common mode voltage in two separate common mode signals.

Resistor 160 has a first terminal connected to WIRE 1 and a second terminal connected node 169. Resistor 162 has a first terminal connected to WIRE 2 and a second terminal connected to node 169. Resister 164 has a first terminal connected to WIRE 3 and a second terminal connected to the node 169. Resistor 166 has a first terminal connected to WIRE 4 and a second terminal to node 169. Resistors 160, 162, 164, and 166 may be typical linear resistors, but these resistive elements may also be replaced by transistors which achieve a similar type of impedance at the voltages that are utilized. In current integrated circuits a typical power supply voltage VDD would be 1.8 to 2.5 volts. It is clear the industry is moving to lower and lower voltages, so VDD may be a lower voltage. This could also result in the voltage differential between WIRE 1 and WIRE 2 being less than 600 mvolts. That would not present a problem or a different approach in concept to that illustrated in FIG. 5.

The result of the configuration illustrated in FIG. 5 is that four differential wires are utilized to produce not just two differential signals, but three. As differential signals they are thus potentially high-speed. Thus, there is an increase in differential signals of one for every two that are generated using two lines per differential signal. Thus, for a given number of pins you get a 50 percent increase in the number of differential signals that are available. The differential signals are ones that can be operated at high speed. Further, these three data signals, DATA 1, DATA 2 and DATA 3 do not have to be synchronized with each other for this operation.

FIG. 6 illustrates one possible embodiment of a transmission circuit 150 of FIG. 5. Alternate circuits may be used to implement transmission circuit 150 of FIG. 5. In the illustrated embodiment, transmission circuit 150 of FIG. 6 includes p-channel field effect transistors (FETs) 300, 304, 308, 310, and 314, n-channel FETs 301-303, 305-307, 309, 311-313, and 315-317, and resistors 120 and 121 coupled in the illustrated manner. Current steering driver circuit 318 includes transistors 300-303 and 305-306. Current steering driver circuit 319 includes transistors 310-313 and 315-316. Current steering driver circuit 320 includes transistors 304, 307, 308, 309, 214, and 317.

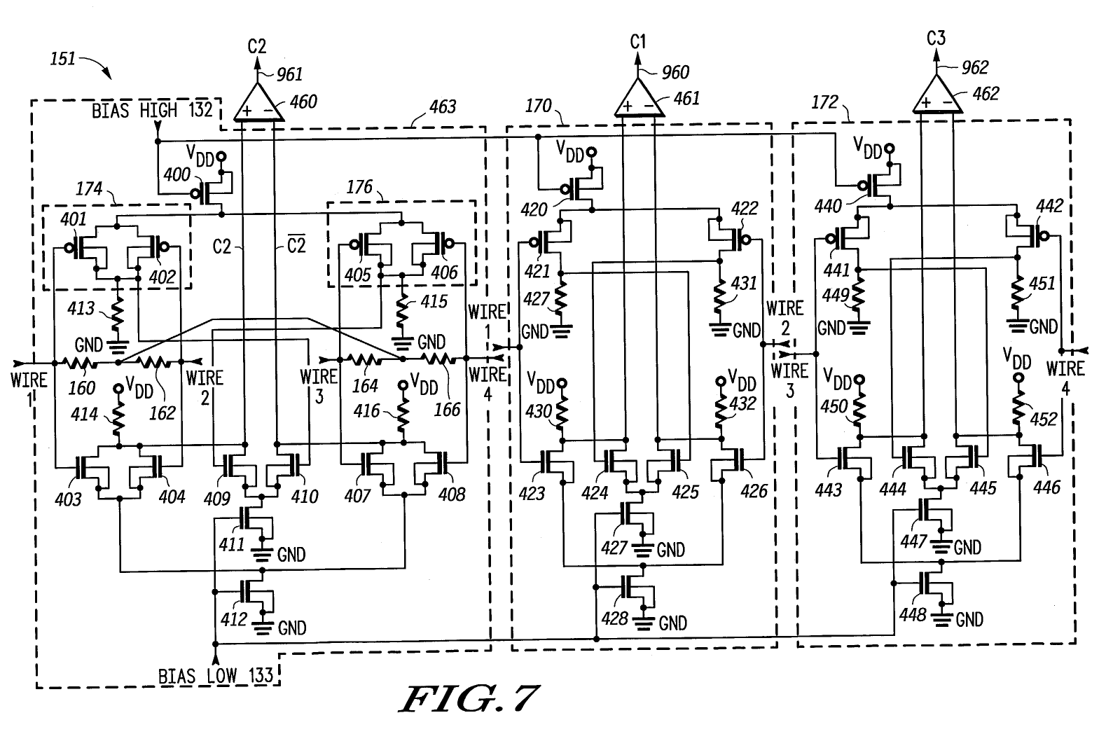

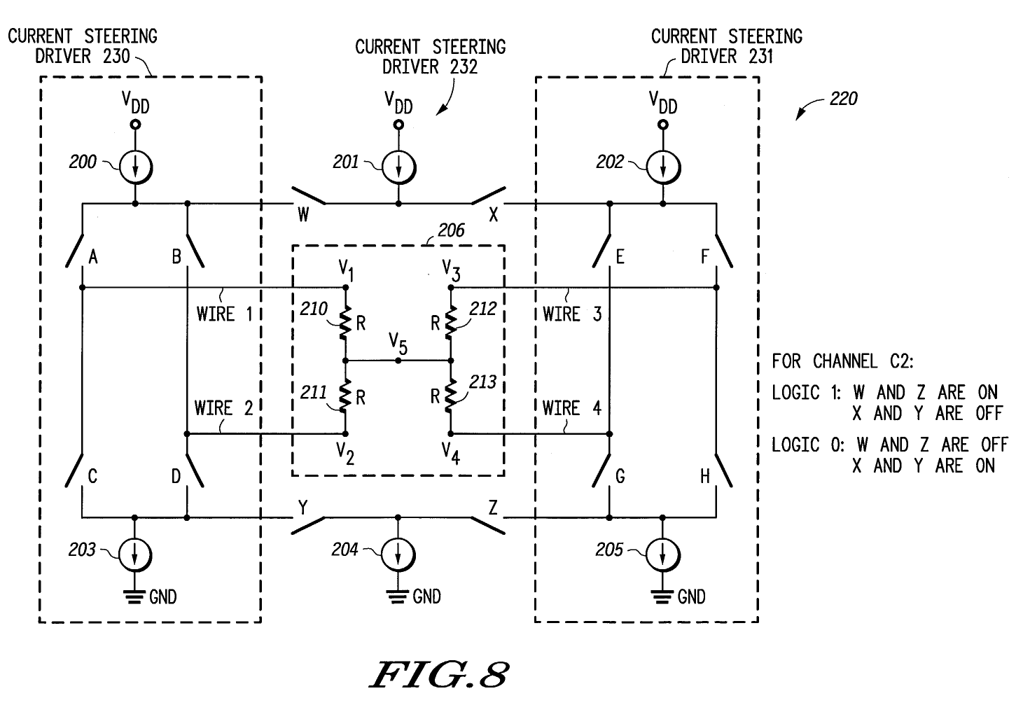

FIG. 7 illustrates one possible embodiment of a receiving circuit 151 of FIG. 5. Alternate circuits may be used to implement receiving circuit 151 of FIG. 5. In the illustrated embodiment, receiving circuit 151 of FIG. 7 includes p-channel field effect transistors (FETs) 400-402, 405-406, 420422, 440-442, n-channel FETs 403-404, 407-412, 423-428, and 443-448, resistors 160, 162, 164, 166, 413-416, 427, 430-432, and 449-452, and comparators 460-462 which are coupled in the illustrated manner to provide channels C1 960, C2 961, and C3 962 as outputs. Receiving circuit 151 includes amplifier circuit 463 and differential amplifiers 170 and 172.

FIG. 8 illustrates a circuit diagram representation of one embodiment of a transmission circuit and a portion of a receiving circuit 220. The receiving circuit portion of circuit 220 is labeled as circuit 206. Two current steering drivers 230, 231 are combined with a third current source with associated switches (current steering driver 232). Switches A, B, C, and D drive channel 1. Switches E, F, G, and H drive channel 2. Switches W, X, Y, and Z drive channel 3. The loads for channels 1 and 2 are split into approximately equal amounts, for example, 50 ohms in one embodiment, and the center taps are shorted together. Note that alternate embodiments may use various appropriate resistive values. Channels 1 and 2 are unaffected by the taps in the load resistors. In this arrangement, channels 1 and 2 operate just like a standard driver.

Channel 3 operates just like channels 1 and 2 in a current steering fashion. The current is steered through half of the load for channel 1 and half of the load for channel 2. The total load is then the same as for channels 1 and 2. Which half of the channel 1 load is used depends on the logic state of channel 1. Similarly for channel 2. The channel 3 current does not affect the logic state of channel 1 or 2 because the signal is common mode and rejected by the channel's receiver.

All three channels operate in a fully current steering mode, so the overall driver is current steering. All three channels operate independently. All three channels are full speed. Note also that the illustrated embodiment of the present invention allows for substantially constant current operation.

The receivers recover the signals on the three channels using differential comparators. For channel 1, the signal is recovered with V₁−V₂, while for channel 2, the signal is V₃-V₄. For channel 3, the difference in the common mode signals from channels 1 and 2 form the recovered signal as (V₁+V₂)/2−(V₃+V₄)/2. This relationship can be rearranged so that channel 3 only requires differential amplifiers. The divisor of 2 can be dropped since only comparators are needed; then channel 3 can also be recovered by (V₁−V₃) −(V₄−V₂).

Note that FIG. 8 may be implemented using a wide variety of circuits. For example, FIG. 8 may implemented using transistors on an integrated circuit. For example, FIG. 8 may implemented using the circuit illustrated in FIG. 6. In the embodiment illustrated in FIG. 6, two resistors, namely resistors 120 and 121 have been added to prevent the current sources 303, 300, 313, and 310 from dropping out of saturation during the momentary instant when all four switches are off during logic transitions. Without the resistors, the imperfect current sources may allow common-mode spikes to appear on channels 1 and 2 during logic transitions on those channels. Since channel 3 utilizes the common-mode voltages on these channels, the spikes represent a significant source of noise on channel 3. The resistors minimize the size of the common-mode voltage spike on channel 3.

Alternate embodiments of the present invention may handle the above =circuit problem in other ways. For example, the common-mode spikes that resistors 120 and 121 control could also be avoided by more careful control of the turn-on and turn-off timing of the switches 301, 302, 305, and 306 in channel 1, and switches 311, 312,315, and 316 in channel 2. Alternate embodiments of the present invention may use a predriver with such control to avoid the use of the resistors 120 and 121, since the use of resistors will likely increase power dissipation by the circuit. The common-mode spikes can also be controlled through judicious use of capacitors to help buffer the voltage changes during signal transition. However this implementation may be less desirable because the basic circuit relies on current sources, which do not control voltage. Adding capacitors to control voltage may decrease the effectiveness of current sources. Alternate designs may use n-channel FETs for transistors 304 and 314 to avoid mismatches between p-channel and n-channel FETs. Note that current steering designs often work better when the switches are either all n-channel FETs or all p-channel FETs. Note that the multi-channel differential signaling driver illustrated in FIG. 6 requires bias voltages for the current sources. Any appropriate circuits may be used to provide the required bias voltages. In one embodiment, a replica bias circuit may be used. Alternate embodiments of the present invention may use any appropriate circuit to implement FIG. 8.

The present invention includes a driver circuit which allows signaling of three independent, high-speed differential channels on only four wires. In addition, the circuit is low-power, process insensitive, and low noise. The current steering nature of the driver circuit maintains the noise benefits of high-speed differential signaling.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. Thus, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A multiple channel driver circuit, comprising:
a first current-steering driver circuit having a first shared portion and a first input for which receives a first channel signal;
a second current-steering driver circuit having a second shared portion and a second input which receives a second channel signal; and
a third current-steering driver circuit, coupled to the first and second current-steering driver circuits, having a third input which receives a third channel signal and using the first and second shared portions to selectively adjust common mode voltages of the first and second current-steering driver circuits.

2. The multiple channel driver circuit of claim 1, wherein each of the first, second, and third current-steering driver circuits draws a substantially constant current.

3. The multiple channel driver circuit of claim 1, wherein:
the first current-steering driver circuit includes switches coupled to the first input, wherein, in response to the first channel signal, current is steered through the first current-steering driver circuit; and
the second current-steering driver circuit includes switches coupled to the second input, wherein, in response to the second channel signal, current is steered through the second current-steering driver circuit.

4. The multiple channel driver circuit of claim 3, wherein:
the third current-steering driver circuit includes switches coupled to the third input, wherein, in response to the third channel signal, current is steered through the third current-steering driver circuit.

5. The multiple channel driver circuit of claim 4, wherein the first shared portion includes at least one of the switches of the first current-steering driver circuit, and the second shared portion includes at least one of the switches of the second current-steering driver circuit.

6. The multiple channel driver circuit of claim 1, wherein the first current-steering driver circuit further comprises:
a first current source coupled to a first power supply;
a second current source coupled to a second power supply;
a first switch having a first terminal coupled to the first current source, a second terminal coupled to a first output of the first current-steering driver circuit, and a control terminal coupled to receive the first channel signal;
a second switch having a first terminal coupled to the first current source, a second terminal coupled to a second output of the first current-steering driver circuit, and a control terminal coupled to receive a complement of the first channel signal;
a third switch having a first terminal coupled to the first output of the first current-steering driver circuit, a second terminal coupled to the second current source, and a control terminal coupled to receive the complement of the first channel signal; and
a fourth switch having a first terminal coupled to the second output of the first current-steering driver circuit, a second terminal coupled to the second current source, and a control terminal coupled to receive the first channel signal.

7. The multiple channel driver circuit of claim 6, wherein the second current-steering driver circuit further comprises:
a first current source coupled to the first power supply;
a second current source coupled to the second power supply;
a first switch having a first terminal coupled to the first current source, a second terminal coupled to a first output of the second current-steering driver circuit, and a control terminal coupled to receive the second channel signal;
a second switch having a first terminal coupled to the first current source, a second terminal coupled to a second output of the second current-steering driver circuit, and a control terminal coupled to receive a complement of the second channel signal;
a third switch having a first terminal coupled to the first output of the second current-steering driver circuit, a second terminal coupled to the second current source, and a control terminal coupled to receive the complement of the second channel signal; and
a fourth switch having a first terminal coupled to the second output of the second current-steering driver circuit, a second terminal coupled to the second current source, and a control terminal coupled to receive the second channel signal.

8. The multiple channel driver circuit of claim 7, wherein the third current-steering driver circuit further comprises:
a first current source coupled to the first power supply;
a second current source coupled to the second power supply;
a first switch having a first terminal coupled to the first current source, a second terminal coupled to the first terminal of the first switch of the first current-steering driver circuit, and a control terminal coupled to receive a complement of the third channel signal;
a second switch having a first terminal coupled to the first current source, a second terminal coupled to the first terminal of the first switch of the second current-steering driver circuit, and a control terminal coupled to receive the third channel signal;
a third switch having a first terminal coupled to the second terminal of the third switch of the first current-steering driver circuit, a second terminal coupled to the second current source, and a control terminal coupled to receive the complement of the third channel signal; and
a fourth switch having a first terminal coupled to the second terminal of the third switch of the second current-steering driver circuit, a second terminal coupled to the second current source, and a control terminal coupled to receive the third channel signal.

9. A multiple channel receiver circuit, comprising:
a first differential amplifier having a first input which receives a first input signal, a second input which receives a second input signal, and an output which provides a first received channel signal;
a second differential amplifier having a first input which receives a third input signal, a second input which receives a fourth input signal, and an output which provides a second received channel signal; and
a summing differential amplifier having a first input which receives the first input signal, a second input which receives the second input signal, a third input which receives the third input signal, a fourth input which receives the fourth input signal, and an output which provides a third received channel signal, the third received channel signal derived from common mode voltages of the first, second, third, and fourth signals.

10. The multiple channel receiver circuit of claim 9, wherein the summing differential amplifier further comprises:
a first summer having a first input which receives the first input signal, a second input which receives the second input signal, and an output which provides a first common mode signal;
a second summer having a first input which receives the third input signal, a second input which receives the fourth input signal, and an output which provides a second common mode signal; and
a differential amplifier having a first input which receives the first common mode signal, a second input which receives the second common mode signal, and an output which provides the third received channel signal.

11. The multiple channel receiver circuit of claim 9, further comprising:
a first resistive element having a first terminal coupled to the first input of the first differential amplifier;
a second resistive element having a first terminal coupled to the second input of the first differential amplifier, and a second terminal coupled to a second terminal of the first resistive element;
a third resistive element having a first terminal coupled to the first input of the second differential amplifier and a second terminal coupled to the second terminal of the first resistive element; and
a fourth resistive element having a first terminal coupled to the second terminal of the third resistive element and a second terminal coupled to the second input of the second differential amplifier.

12. An amplifier circuit, comprising:
a first input which receives a first input signal;
a second input which receives a second input signal;
a third input which receives a third input signal;
a fourth input which receives a fourth input signal;
a first summing circuit coupled to the first input and the second input and having an output which provides a first sum of the first input signal and the second input signal;
a second summing circuit coupled to the third input and the fourth input and having an output which provides a second sum of the third input signal and the fourth input signal;
a first differential output which provides a first difference between the first and second sums; and
a second differential output which provides a complement of the first difference.

13. The amplifier circuit of claim 12, wherein the first summing circuit comprises:
a first transistor having a control electrode coupled to the first input, a first current electrode, and a second current electrode coupled to the first differential output; and
a second transistor having a control electrode coupled to the second input, a first current electrode coupled to the first current electrode of the first transistor, and a second current electrode coupled to the first differential output.

14. The amplifier circuit of claim 13, wherein the second summing circuit comprises:
a first transistor having a control electrode coupled to the third input, a first current electrode, and a second current electrode coupled to the second differential output; and
a second transistor having a control electrode coupled to the fourth input, a first current electrode coupled to the first current electrode of the first transistor of the second summing circuit, and a second current electrode coupled to the second differential output.

15. The amplifier circuit of claim 12, further comprising:
a first mirror circuit comprising the first summing circuit and the second summing circuit, wherein the first mirror circuit includes transistors having a first conductivity type; and
a second mirror circuit, coupled to the first mirror circuit, comprising:
a first summing circuit coupled to the first input and the second input and having an output for providing a first sum of the first input signal and the second input signal; and
a second summing circuit coupled to the third input and the fourth input and having an output for providing a second sum of the third input signal and the fourth input signal, wherein the second mirror circuit includes transistors having a second conductivity type.

16. The amplifier circuit of claim 15, wherein the first conductivity type is N-type and the second conductivity type is P-type.

17. The amplifier circuit of claim 15, further comprising a differential amplifier having a first terminal coupled to the first summing circuit of the first mirror circuit, a second terminal coupled to the second summing circuit of the first mirror circuit, a third terminal coupled to first summing circuit of the second mirror circuit, and a fourth terminal coupled to the second summing circuit of the second mirror circuit.

18. A multiple channel driver and receiver circuit, comprising:
a first current-steering driver circuit having an input which receives a first channel signal, a first output which provides a first output signal, a second output which provides a second output signal, and a first shared portion;
a second current-steering driver circuit having a first input which receives a second channel signal, a first output which provides a third output signal, a second output which provides a fourth output signal, and a second shared portion;
a third current-steering driver circuit, coupled to the first and second current-steering driver circuits, having a third input which receives a third channel signal and uses the first and second shared portions to selectively adjust common mode voltages of the first and second current-steering driver circuits;
a first differential amplifier having a first input which receives the first output signal, a second input which receives the second output signal, and an output which provides a first received channel signal;
a second differential amplifier having a first input which receives the third output signal, a second input which receives the fourth output signal, and an output which provides a second received channel signal; and
a summing differential amplifier having a first input which receives the first output signal, a second input which receives the second output signal, a third input which receives the third output signal, a fourth input which receives the fourth output signal, and an output which provides a third received channel signal, the third received channel signal derived from a first common mode voltage of the first and second output signals and a second common mode voltage of the third and fourth output signals.

19. A method for transmitting multiple channel signals, comprising:
receiving a first channel signal;
in response to receiving the first channel signal, steering a first current through a first shared switch;
receiving a second channel signal;
in response to receiving the second channel signal, steering a second current through a second shared switch;
receiving a third channel signal; and
in response to receiving the third channel signal, steering a third current through at least one of the first shared switch and the second shared switch.

20. A multiple channel driver circuit, comprising:
first receiving means for receiving a first channel signal;
second receiving means for receiving a second channel signal;
third receiving means for receiving a third channel signal;
first steering means for steering a first current through a first shared switch in response to receiving the first channel signal;
second steering means for steering a second current through a second shared switch in response to receiving the second channel signal; and
third steering means for steering a third current through at least one of the first shared switch and the second shared switch in response to receiving the first channel signal.

21. The multiple channel driver circuit of claim 20, wherein the third steering means comprises adjusting means for selectively adjusting common mode voltages corresponding to the first steering means and the second steering means.

22. A method for receiving multiple differential channel signals, comprising:
receiving a first input signal and a second input signal, the first input signal and the second input signal corresponding to a first differential signal;
receiving a third input signal and a fourth input signal, the third input signal and the fourth input signal corresponding to a second differential signal, and the first differential signal and the second differential signal corresponding to a third differential signal;
providing a first received channel signal corresponding to the first differential signal;
providing a second received channel signal corresponding to the second differential signal; and
providing a third received channel signal corresponding to the third differential signal.

23. The method of claim 22, wherein providing the third received channel signal comprises:
combining the first input signal and the second input signal to form a first combined signal;
combining the third input signal and the fourth input signal to form a second combined signal; and
comparing the first combined signal and the second combined signal to form the third received channel signal.

24. A multiple channel receiver, comprising:
first receiving means for receiving a first input signal and a second input signal, the first input signal and the second input signal corresponding to a first differential signal;
second receiving means for receiving a third input signal and a fourth input signal, the third input signal and the fourth input signal corresponding to a second differential signal, and the first differential signal and the second differential signal corresponding to a third differential signal;
first providing means for providing a first received channel signal corresponding to the first differential signal;
second providing means for providing a second received channel signal corresponding to the second differential signal; and
third providing means for providing a third received channel signal corresponding to the third differential signal.

25. The multiple channel receiver of claim 24, wherein the third providing means comprises:
first combining means for combining the first input signal and the second input signal to form a first combined signal;
second combining means for combining the third input signal and the fourth input signal to form a second combined signal; and
comparing means for comparing the first combined signal and the second combined signal to form the third received channel signal.
